(19) United States
(12) Patent Application Publication
(10) Pub. No.: US 2026/0371513 A1
(43) Pub. Date: Nov. 19, 2026

(54) Frequency Converter Back Panel and Frequency Converter

(71) Applicant: Siemens Aktiengesellschaft, MÜnchen (DE)

(72) Inventors: Ming Zhou, Nanjing, JS (CN); Kai Kaii Li, Nanjing, JS (CN); Jing Bo Hu, Nanjing, JS (CN); Zi Ang Zhao, Nanjing, JS (CN)

(73) Assignee: Siemens Aktiengesellschaft, MÜnchen (DE)

(21) Appl. No.: 19/470,608

(22) PCT Filed: Mar. 31, 2023
(86) PCT No.: PCT/CN2023/085633

§ 371 Date: Sep. 29, 2025

(51) Int. Cl. H05K 7/12; H05K 7/14

(52) U.S. Cl. CPC H05K 7/12; H05K 7/1432; H05K 7/1438

(57) ABSTRACT

Various embodiments of the teachings herein include a frequency converter back panel. An example includes: a back panel body having a side plate and a bottom plate; and a guiding component mounted on an inner wall of the side plate. A first end of the guiding component is aligned with a screw hole on the bottom plate. Once the screw hole is aligned with a corresponding screw hole of a core module, a second end of the guiding component can be aligned with the corresponding screw hole. During assembling of the back panel body and the core module, the guiding component operates to guide a screw used to connect the screw hole on the bottom plate of the back panel body and the screw hole on the core module. The core module comprises an electric circuit functional module assembled with the frequency converter back panel.

### CROSS-REFERENCE TO RELATED APPLICATIONS

This application is a U.S. National Stage Application of International Application No. PCT/CN2023/085633 filed Mar. 31, 2023, which designates the United States of America, the contents of which are hereby incorporated by reference in their entirety.

### TECHNICAL FIELD

The present disclosure relates to frequency converters. Various embodiments of the teachings herein include systems and/or methods for frequency converter back panels and frequency converters.

### BACKGROUND

During typical assembling of a frequency converter, it is necessary to connect a core module and a back panel by a screw. However, it is a relatively long mounting path for the screw, about 114.5 mm. Moreover, as the back panel is opaque and its screw hole is small, a problem often happens during screw mounting is that the screw can not be aligned with a screw hole of the core module.

### SUMMARY

In the embodiments of the present invention, a frequency converter back panel and a frequency converter are provided, which can provide guiding to the screw during mounting of the frequency converter back panel. For example, some embodiments include a frequency converter back panel, characterized in that it comprises a back panel body and a guiding component wherein the back panel body comprises a side plate and a bottom plate; the guiding component is mounted on an inner wall of the side plate of the back panel body; and one end of the guiding component is aligned with a screw hole on the bottom plate of the back panel body, and after the screw hole of the back panel body is aligned with a screw hole of a core module, another end of the guiding component can be aligned with the screw hole on the core module; during assembling of the back panel body and the core module, the guiding component can bear a screw to guide the screw, the screw is used to connect the screw hole on the bottom plate of the back panel body and the screw hole on the core module; the core module is an electric circuit functional module assembled with the frequency converter back panel.

In some embodiments, the back panel body comprises two side plates opposite to each other, and the back panel body has a cross section in U shape; and the frequency converter back panel comprises at least one pair of the guiding components wherein in each pair of the guiding components, one guiding component is mounted on the inner wall of one of the side plates of the back panel body, and the other guiding component is mounted on the inner wall of the other of the side plates of the back panel body.

In some embodiments, the guiding component is provided thereon with a flexed part, and the side plate of the back panel body is provided thereon with a clamping slot, wherein the flexed part of the guiding component can be inserted into the clamping slot on the back panel body such that the guiding component is mounted on the inner wall of the side plate of the back panel body.

In some embodiments, both the flexed part and the clamping slot have a T shape wherein a long side of the T shape of the flexed part can be inserted in to a long side of the T shape of the clamping slot; after sliding of the guiding component, a short side of the T shape of the clamping slot can clamp a short side of the T shape of the flexed part on the guiding component such that the flexed part is inserted into the clamping slot.

In some embodiments, the guiding component comprises a hollow column having a longitudinal opening and two folded edges provided at the longitudinal opening, and the guiding component has a cross section in Ω shape.

In some embodiments, the flexed part is provided on at least one of the folded edges of the guiding component.

In some embodiments, the side plate of the back panel body is provided thereon with a flexed side; the flexed part has a height in a longitudinal direction of the folded edge matched with a height of the flexed side of the back panel body such that after the flexed part is inserted into the clamping slot, the guiding component is prevented from longitudinal movement.

In some embodiments, the screw hole on the bottom plate of the back panel body is provided at an edge of the bottom plate.

As another example, some embodiments include a frequency converter, characterized in that it comprises a core module and any of the frequency converter back panels as described herein, the screw hole on the core module and the screw hole on the bottom plate of the back panel body of the frequency converter back panel are connected by the screw, and the screw is within the guiding component.

In some embodiments, the core module has a flexed side, and the screw hole on the core module is provided on the flexed side of the core module.

### BRIEF DESCRIPTION OF THE DRAWINGS

The figures in the description below depict only some embodiments of the teachings of the present disclosure. Based on these figures, those skilled in the art can obtain other figures without any inventive work. In the drawings:

FIG. 1 shows an external view of a side plate of a back panel body and the guiding component mounted on the side plate incorporating teachings of the present disclosure;

FIG. 2 shows an internal view of a side plate of a back panel body and a guiding component mounted on the side plate incorporating teachings of the present disclosure;

FIG. 3 shows a bottom view of a bottom plate of a back panel body incorporating teachings of the present disclosure;

FIG. 4 shows a cross section of a back panel body incorporating teachings of the present disclosure;

FIG. 5 shows an entire structure of a guiding component incorporating teachings of the present disclosure;

FIG. 6 shows a flexed part of the guiding component incorporating teachings of the present disclosure;

FIG. 7 shows a state after the flexed part of a guiding component is inserted into a clamping slot on a back panel body incorporating teachings of the present disclosure; and

FIG. 8 shows positions of the flexed edge on a back panel body and a flexed part incorporating teachings of the present disclosure.

### REFERENCE NUMERALS

| | |
|---|---|
| 10 | one side plate of back panel body |
| 20 | guiding component |
| 11 | inner wall of one side plate of back panel body |
| 30 | bottom plate of back panel body |
| 31 | screw hole on bottom plate of back panel body |
| 21 | hollow column having longitudinal opening |
| 22 | folded edge provided at longitudinal opening |
| 23 | flexed part |
| 12 | clamping slot on side plate of back panel body |
| 13 | flexed side on side plate of back panel body |

### DETAILED DESCRIPTION

Some embodiments of the teachings herein include a frequency converter back panel, comprising a back panel body and a guiding component wherein: the back panel body comprises a side plate and a bottom plate; the guiding component is mounted on an inner wall of the side plate of the back panel body; and one end of the guiding component is aligned with a screw hole on the bottom plate of the back panel body, and after the screw hole of the back panel body is aligned with a screw hole of a core module, another end of the guiding component can be aligned with the screw hole on the core module; during assembling of the back panel body and the core module, the guiding component can bear a screw to guide the screw, the screw is used to connect the screw hole on the bottom plate of the back panel body and the screw hole on the core module; the core module is an electric circuit functional module assembled with the frequency converter back panel.

Some embodiments include a frequency converter, comprising a core module and the frequency converter back panel as provided in the first aspect, the screw hole on the core module and the screw hole on the bottom plate of the back panel body of the frequency converter back panel are connected by the screw, and the screw is within the guiding component.

The frequency converter back panel and the frequency converter, individually or in combination, may provide that, during assembly, the guiding component can guide the screw such that the screw can be aligned with the screw hole of the core module even if the frequency converter back panel is opaque or the screw hole of the back panel is relatively small. Moreover, if the screw falls during assembling, it will fall to a region within the guiding component, rather than other regions. Therefore, it is not necessary to disassemble the whole frequency converter back panel for removing the screw, and rather, the screw will drop out when the frequency converter back panel is inverted. Therefore, the assembling efficiency of the frequency converter can be higher and the maintenance experience can be improved.

In some embodiments, the short side of the T shape of the flexed part on the guiding component is clamped at the short side of the T shape of the clamping slot and will not move left/right due to limitation by the short side of the clamping slot. That is, the lateral movement of the flexed part is limited. Moreover, as the limitation to the long side of the flexed part and the guiding component, not only the vertical movement but also the forward/backward movement thereof is prevented.

In some embodiments, the inner wall of the side plate of the back panel body is provided thereon with a flexed side having a height matched with a height of the flexed part in a direction of an central axis of the guiding component such that after the flexed part is inserted into the clamping slot, the guiding component is prevented from longitudinal movement, due to limitation by the flexed side.

In order to make the objectives, technical solutions, and potential advantages of the present disclosure clearer, example technical solutions are described hereinafter in connection with the figures. The described embodiments are exemplary only, rather than all embodiments. Any other embodiments obtained based on the embodiments described by those skilled in the art without any inventive work will fall within the protection scope of the present disclosure.

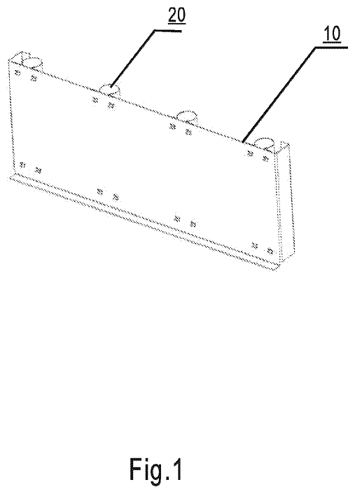

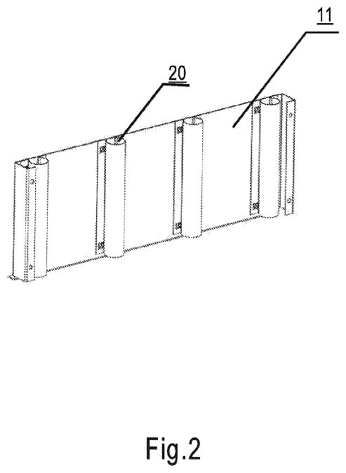

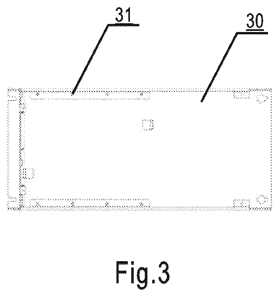

Some embodiments of the present disclosure include a frequency converter back panel. Referring to FIGS. 1, 2 and 3, the frequency converter back panel shown comprises a back panel body and a guiding component 20 wherein: the back panel body comprises a side plate 10 and a bottom plate 30; the guiding component 20 is mounted on an inner wall 11 of the side plate 10 of the back panel body; and one end of the guiding component 20 is aligned with a screw hole 31 on the bottom plate 30 of the back panel body, and after the screw hole of the back panel body is aligned with a screw hole of a core module, another end of the guiding component 20 can be aligned with the screw hole on the core module; during assembling of the back panel body and the core module, the guiding component 20 can bear a screw to guide the screw, the screw is used to connect the screw hole 31 on the bottom plate 30 of the back panel body and the screw hole on the core module; the core module is an electric circuit functional module assembled with the frequency converter back panel.

During assembling of the frequency converter, it may be necessary to assemble the frequency converter back panel and the core module.

Each of the frequency converter back panel and the core module is provided thereon with a screw hole, and thus it is possible to use the screw and the screw holes to connect the frequency converter back panel and the core module, thereby achieving assembling of them.

As shown, the back panel body comprises a side plate and a bottom plate. The screw hole on the back panel body is provided on the bottom plate. The guiding component is mounted on an inner wall of the side plate. One end of the guiding component is aligned with the screw hole on the bottom plate, and after the screw hole of the back panel body is aligned with a screw hole of a core module, another end of the guiding component is aligned with the screw hole on the core module.

Herein, the core module is an electric circuit functional module of the frequency converter and may be any one of a plurality of functional modules.

During assembling, first, the screw holes of the back panel body and the core module are aligned with each other, and then the screw is inserted from the screw hole of the bottom plate of the back panel body. With the limitation by the guiding component, the screw is rotated and screwed into the screw hole of the core module for locking, thus achieving assembling of the back panel body and the core module.

Herein, the screw hole on the bottom plate of the back panel body may be provided at an edge of the bottom plate.

Herein, the guiding component may be a sheet metal part.

As can be seen, during assembling of the frequency converter back panel, the guiding component can guide the screw, and the screw can be aligned with the screw hole of the core module even if the frequency converter back panel is opaque or the screw hole of the back panel is relatively small. Moreover, if the screw falls during assembling, it will fall to a region within the guiding component, rather than other regions. Therefore, it is not necessary to disassemble the whole frequency converter back panel for removing the screw, and rather, the screw will drop out when the frequency converter back panel is inverted. Therefore, the assembling efficiency of the frequency converter can be higher and the maintenance experience can be improved.

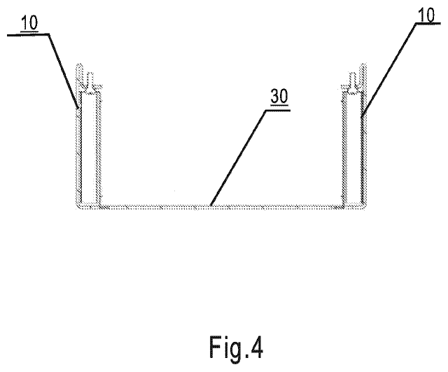

In some embodiments, as shown in FIG. 4, the back panel body may comprise two side plates 10 opposite to each other, and the back panel body has a cross section in U shape; the frequency converter back panel comprises at least one pair of the guiding components wherein in each pair of the guiding components, one guiding component is mounted on the inner wall of one of the side plates of the back panel body, and the other guiding component is mounted on the inner wall of the other of the side plates of the back panel body.

Herein, as the back panel body comprises two side plates opposite to each other and one bottom plate, it can be seen that the back panel body has a cross section in U shape. On the inner wall of the side plates of the back panel body, at least one pair of the guiding components is provided. For example, the bottom plate is provided thereon with three pairs of screw holes, and thus it is possible to provide three pairs of guiding components. In each pair of the guiding components, one guiding component is mounted on the inner wall of one of the side plates, and the other guiding component is mounted on the inner wall of the other of the side plates. In fact, the positions and the number of the guiding components on the inner walls of the side plates depend on the positions and the number of the screw holes on the bottom plate. In this manner, the frequency converter back panel and the core module can be mounted together more firmly.

In some embodiments, the guiding component is provided thereon with a flexed part, and the side plate of the back panel body is provided thereon with a clamping slot, wherein the flexed part of the guiding component can be inserted into the clamping slot on the back panel body such that the guiding component is mounted on the inner wall of the side plate of the back panel body.

Some embodiments include a method for mounting the guiding component onto the inner wall of the side plate. The guiding component is provided thereon with a flexed part which refers to a portion from the guiding component being flexed to form a clamping part. The side plate of the back panel body is provided thereon with a clamping slot. The flexed part is inserted into the clamping slot such that the guiding component is mounted on the back panel body.

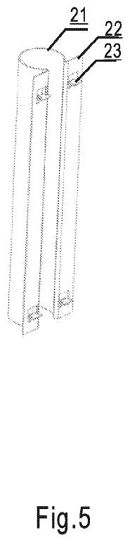

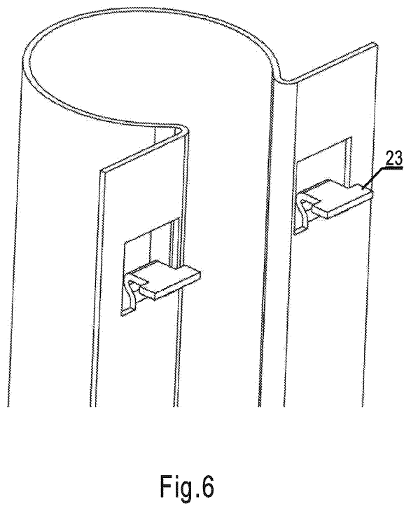

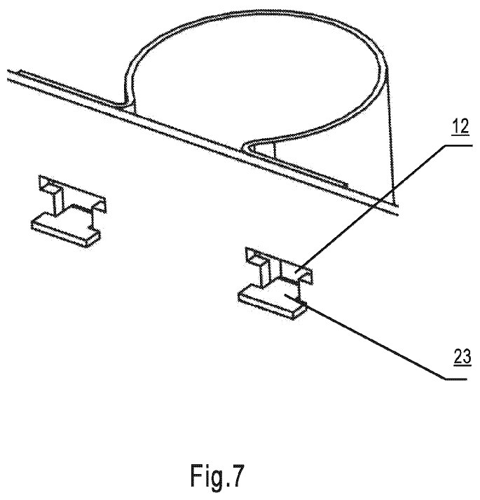

In some embodiments, as shown in FIGS. 5, 6 and 7, both the flexed part 23 and the clamping slot 12 have a T shape wherein a long side of the T shape of the flexed part can be inserted in to a long side of the T shape of the clamping slot; after sliding of the guiding component, a short side of the T shape of the clamping slot can clamp a short side of the T shape of the flexed part on the guiding component such that the flexed part is inserted into the clamping slot.

That is, the flexed part and the clamping slot are consistent in shape. However, the flexed part is formed by flexing on the guiding component, and the clamping slot is formed by slot-formation on the back panel body. As can be seen, the flexed part and the clamping slot are different in orientation. That is, the clamping slot is within a plane of the back panel body, while there is an angle between the flexed part and the guiding component. Therefore, the flexed part can be clamped on the back panel body.

In some embodiments, the flexed part has a T shape. That is, the flexed part comprises a long side and a short side wherein the long side and the short side are named comparatively. The clamping slot also comprises a long side and a short side. The short side of the flexed part in T shape may refer to the vertical side of the “T” shape and the long side of the flexed part in T shape may refer to the horizontal side of the “T” shape. First, the long side of the flexed part is inserted into the long side of the clamping slot. After the long side of the flexed part passes through the long side of the clamping slot, the flexed part slides downwards to the bottom such that the short side of the flexed part is clamped on the short side of the clamping slot, thus the flexed part is inserted in the clamping slot.

As the short side of the T shape of the flexed part on the guiding component is finally clamped on the short side of the T shape of the clamping slot. The short side of the flexed part will not move left/right due to limitation by the short side of the clamping slot. That is, the lateral movement of the flexed part is limited. Moreover, as the limitation to the long side of the flexed part and the guiding component, not only the vertical movement but also the forward/backward movement thereof is prevented.

In some embodiments, as shown in FIG. 5, the guiding component may comprise a hollow column 21 having a longitudinal opening and two folded edges 22 provided at the longitudinal opening, and the guiding component has a cross section in Ω shape. That is, the guiding component may be a hollow column having a longitudinal opening, with two folded edges provided at the longitudinal opening. Thus, the guiding component has a cross section in Ω shape. As the screw also has a column-shape structure, the guiding component as a hollow column is matched with it. Moreover, two folded edges are provided at the longitudinal opening. The two folded edges form a plane, thus facilitating mounting the guiding component onto the back panel body.

Furthermore, the flexed part may be provided on at least one of the folded edges 22 of the guiding component. That is, the flexed part is provided on the folded edge of the guiding component. Thus, after the flexed part is inserted into the clamping slot, the plane of the folded edges is closely fit with the plane of the back panel body such that the guiding component is firmly mounted on the back panel body.

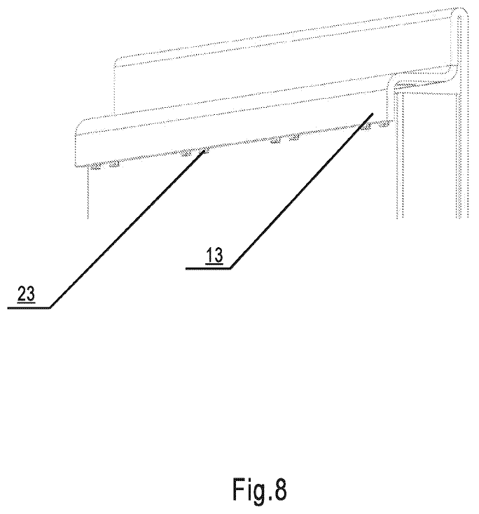

In some embodiments, like that shown in FIG. 8, the side plate of the back panel body may be provided thereon with a flexed side 13; the flexed part has a height in a longitudinal direction of the folded edge matched with a height of the flexed side 13 of the back panel body such that after the flexed part is inserted into the clamping slot, the guiding component is prevented from longitudinal movement.

Herein, the height of the flexed part in a longitudinal direction of the folded edge refers to the height of the flexed part in a direction of a central axis of the guiding component. That is, the inner wall of the side plate of the back panel body is provided thereon with a flexed side having a height matched with a height of the flexed part in a direction of an central axis of the guiding component such that after the flexed part is inserted into the clamping slot, the guiding component is prevented from longitudinal movement, due to limitation by the flexed side. Due to some limitations, the guiding component with the above structure will not move forward/backward, or left/right, or vertically, thus achieving secure connection of the guiding component, without any additional connection accessories.

Some embodiments of the teachings herein include a frequency converter. The frequency converter comprises a core module and the frequency converter back panel as provided in the first aspect, the screw hole on the core module and the screw hole on the bottom plate of the back panel body of the frequency converter back panel are connected by the screw, and the screw is within the guiding component. That is, after the screw hole on the bottom plate of the back panel body is aligned with the screw hole of the core module, with guiding by the guiding component, the screw is connected with the screw hole of the core module and the screw hole on the bottom plate of the back panel body, thus achieving connection of the core module and the frequency converter back panel.

In some embodiments, the core module has a flexed side, and the screw hole on the core module is provided on the flexed side of the core module. As different core modules may have difference dimensions, in order that the screw hole on the bottom plate of the back panel body can be aligned with the screw hole of the core module, it is possible to provide a flexed side on the core module. Thus, the screw hole of the core module is provided on the flexed side of the core module, improving convenience and adaptability for assembling.

The embodiments in the present description are described in a gradually progressive manner. The same or similar portions between different embodiments can be referred to each other. Each embodiment emphasizes in explaining the difference(s) with respect to other embodiment(s). In particular, as the apparatus/device embodiments are substantially similar to the method embodiments, the description thereof is relatively simple, and the description of the method embodiments may be referred to for the related portions.

With the above-described specific embodiments, the purposes, technical solutions and potential beneficial effects of the present disclosure are further explained in detail. It should be understood that the above description is only for specific embodiments, not for defining the protection scope of the present disclosure. Any variation, equivalent substitution or improvement made based on the technical solutions herein will fall within the protection scope of the present disclosure.

What is claimed is:

1. A frequency converter back panel comprising:
a back panel body having
a side plate and a bottom plate; and
a guiding component mounted on an inner wall of the side plate;
wherein: a first end of the guiding component is aligned with a screw hole on the bottom plate; and once the screw hole is aligned with a corresponding screw hole of a core module, a second end of the guiding component can be aligned with the corresponding screw hole;
during assembling of the back panel body and the core module, the guiding component operates to guide a screw used to connect the screw hole on the bottom plate of the back panel body and the screw hole on the core module; and
the core module comprises an electric circuit functional module assembled with the frequency converter back panel.

2. The frequency converter back panel according to claim 1, wherein:
the back panel body comprises two side plates opposite to each other forming a cross section in U shape; and
the frequency converter back panel comprises a pair of guiding components with one guiding component mounted on the inner wall of one of the side plates of the back panel body, and the other guiding component mounted on the inner wall of the other of the side plates of the back panel body.

3. The frequency converter back panel according to claim 1, wherein:
the guiding component includes a flexed part, and
the side plate of the back panel body includes a clamping slot;
the flexed part of the guiding component can be inserted into the clamping slot on the back panel body such that the guiding component is mounted on the inner wall of the side plate of the back panel body.

4. The frequency converter back panel according to claim 3, wherein:
both the flexed part and the clamping slot have a T shape;
a long side of the T shape of the flexed part can be inserted in to a long side of the T shape of the clamping slot; and
after sliding of the guiding component, a short side of the T shape of the clamping slot can clamp a short side of the T shape of the flexed part on the guiding component such that the flexed part is inserted into the clamping slot.

5. The frequency converter back panel according to claim 4, wherein:
the guiding component comprises a hollow column having a longitudinal opening and two folded edges provided at the longitudinal opening; and
the guiding component has a cross section in Ω shape.

6. The frequency converter back panel according to claim 5, wherein the flexed part is disposed on at least one of the folded edges of the guiding component.

7. The frequency converter back panel according to claim 6, wherein:
the side plate of the back panel body is provided thereon with a flexed side; and
the flexed part has a height in a longitudinal direction of the folded edge matched with a height of the flexed side of the back panel body such that after the flexed part is inserted into the clamping slot, the guiding component is prevented from longitudinal movement.

8. The frequency converter back panel according to claim 1, wherein the screw hole on the bottom plate of the back panel body is disposed adjacent an edge of the bottom plate.

9. A frequency converter comprising:
a core module;
a back panel body having a side plate and a bottom plate; and
a guiding component mounted on an inner wall of the side plate;
wherein a first end of the guiding component is aligned with a screw hole on the bottom plate; and
once the screw hole is aligned with a corresponding screw hole of the core module, a second end of the guiding component can be aligned with the corresponding screw hole;
during assembling of the back panel body and the core module, the guiding component operates to guide a screw used to connect the screw hole on the bottom plate of the back panel body and the screw hole on the core module;
the core module comprises an electric circuit functional module assembled with the frequency converter back panel; and
the screw hole on the core module and the screw hole on the bottom plate of the back panel body of the frequency converter back panel are connected by the screw, and the screw is within the guiding component.

10. The frequency converter according to claim 9, wherein:
the core module has a flexed side; and
the screw hole on the core module is disposed on the flexed side of the core module.
